(19) United States
(12) Patent Application Publication
(10) Pub. No.: US 2011/0317856 A1
(43) Pub. Date: Dec. 29, 2011

(54) HEADPHONE

(76) Inventor: Katsumi Akasu, Tokyo (JP)

(21) Appl. No.: 13/254,305

(22) PCT Filed: Mar. 11, 2010
(86) PCT No.: PCT/JP2010/054090

§ 371 Date: Sep. 1, 2011

(30) Foreign Application Priority Data
Mar. 17, 2009 (JP) 2009-001552

(51) Int. Cl. H03G 3/00; H04R 1/10

(52) U.S. Cl. 381/109; 381/384

(57) ABSTRACT

A headphone can be connected simultaneously to a plurality of audio source devices respectively so the sound information and musical compositions having different contents can be arbitrarily selected and combined to listen to simultaneously. A plurality or plural sets of speaker units are provided to be respectively connected with a plurality of external audio source devices in the inside housing main body of the headphone, and means such as a volume controller and an on-off switch are provided for independently adjusting and operating the electrical signals of the external audio source devices in the appropriate middle position of the connecting cord.

### TECHNOLOGICAL FIELD

The present invention relates to a headphone (including earphones), and further specifically relates to a headphone, which is connected to a plurality of audio source devices at the same time so sound information and musical compositions which are obtained from the respective audio source devices and have different contents can be arbitrarily selected and combined so as to be listened to simultaneously.

### BACKGROUND TECHNOLOGY

The headphone including the earphones is an apparatus which converts an electrical signal input from the external audio source device into sound information and musical compositions and is brought into contact with and held against an auricle of an ear or an opening of the external auditory canal in order to listen to sound information and musical compositions. The headphone has in a hollow housing inside the main body thereof a speaker unit which converts the electrical signal output by the external audio source device into an audio signal to be propagated as air vibration, and a connecting cord one end of which is connected to a terminal of the speaker unit in the main body and the other end of which has a connector such as a plug and a jack for detachably connecting to the external audio source device.

The headphone was developed and used in the past in order to listen to a weak audio signal provided by wireless communication equipment or a radio receiver of low performance with the external sound influence blocked out. Then, estimated was the characteristics thereof in which a propagation of the audio signal to the external open space (so-called a sound leakage) and the external sound influence were suppressed or blocked to allow a person to individually listen without constraint. As a result, in various audio source devices, the capabilities of converting the electrical signal into the audio signal and of amplification and propagation have been sufficiently enhanced. Usage of the headphone has greatly expended even when there is no hindrance to listening using the external speaker. As a result of the spread and permeation of small-sized audio source devices which are easily carried—that is, particularly, digital audio players represented by iPod (registered trademark), digital reproduction equipment for motion pictures and still images, and the like have been tremendously improved in sound quality and increased in the capacity thereof, and various sound information is ordinarily recorded and used using a voice recorder—the usage of the audio source device for listening by the headphone has been remarkably spread irrespective of indoors and outdoors, and it can be said that this has become part of our lives.

In this way, the headphone is presently widely spread and used due to the sound insulation performance thereof of suppressing the external sound influence and the sound leakage to the outside. However, on the contrary, one problem caused by the characteristics is pointed out, and development and provision of the headphone for solving the problem is demanded.

That is, as shown in FIG. 5, the headphone of related art is absolutely assumed to one-to-one correspond to the external audio source device. The headphone of related art has only one or one set of speaker unit 13 to correspond to a single external audio source device provided in a housing 15 in a main body 11 of a headphone 1 which is used in a state of being brought into contact with and held against an auricle of an ear or an opening of the external auditory canal. The headphone of related art is connected to the external single audio source device corresponding to the speaker unit 13 via one connecting cord 14 provided with a connector such as a jack 2, and configured so sound information and musical compositions provided by the audio source device is listened. As a matter of course, the audio source device used for listening by one headphone is limited to one, and sound information and musical compositions of different contents provided from the plural audio source devices cannot be listened by one headphone.

However, nowadays, a wide variety of audio source devices is ordinarily carried and used due to the device being down-sized and down-weighted, and the capacity of the device has increased dramatically by digitalisation, which makes it possible for large amounts and many kinds of sound information and musical compositions to be stored and collected to be always listened to; there are some demands that, for example, the contents of a lecture recorded in a voice recorder or the sound information of a foreign language course received via an FM transmitter stored in an audio player to be arbitrarily combined with the desired musical composition which is stored and collected in another audio player so as to be listened to simultaneously, and the like.

Obviously, one-to-one correspondence between the external audio source device and the speaker unit is not inherent only in the headphone and is generally common in the speakers. With the speaker which amplifies the sound signal and propagates it to open space, if a plurality of speakers respectively coupled to a plurality of different audio source devices are operated, all the different sound information and musical compositions from the respective speakers can be listened to. However, even if there are prepared headphones having a high sound insulation performance in many numbers, it is impossible to wear a plurality of headphones at the same time and listen to the different sound information and musical compositions from the plurality of audio source devices. Further, even if the connector of the connecting cord terminal is branched, the plurality of audio source devices are only easily switched to use and the desired simultaneous listening cannot be achieved.

Moreover, if high-functional digital editing equipment is used, the different sound information and musical compositions of the plurality of audio source devices can be simultaneously input to the editing equipment and instantly output to a single headphone. However, since it is not easy for a general user of the audio source device to operate these digital editing equipment at will, and the demand for simultaneous listening has an assumption which a facile and easy operation is achieved by the external audio source device which is smaller and lighter, highly portable and widespread, this kind of digital editing equipment which is large-sized, lowly portable and heavily dependent on the advanced and complex operation on an output equipment side cannot meet the demand for simultaneous listening.

Further, the different sound information and musical compositions of the plurality of audio source devices can be combined or overlapped to be edited in advance in a personal computer by using relatively easy editing software. However, this is nothing more or less than the utilization of the one-to-one correspondence between the audio source device and the headphone. Therefore, the advance editing process is not only troublesome but also does not meet the demand which the sound information and musical compositions of the plurality of audio source devices are arbitrarily selected and combined to be listened to simultaneously according to the situation and feeling at the time of listening. Moreover, when listening, a volume level of any one of the sound information and the musical composition of each audio source device cannot be tuned up and down, and the operation such as stopping and resuming cannot be performed to the audio source device independently of other audio source devices.

Note that formerly, the one which has a large diameter, is provided with a locking means such as a headband, and is brought into contact with and held against an auricle of an ear for use with the auricle being covered entirely was referred to as a headphone, the one which has a small diameter and is provided with a earplug to be inserted to an external auditory canal and the main body of which is brought into contact with and held at a locking position of an opening of the external auditory canal was referred to as an earphone. However, presently, many so-called headphones which have a small diameter and are used in a state of being locked on an auricle of an ear without the headband, and so-called earphones which are not provided with the earplug locked on a processus cartilaginis of the auricle of an ear so the main body thereof is brought into contact with and positioned on the opening of the external auditory canal are provided. Thus, a clear boundary between the headphone and the earphone is lost with a result in which these listening devices all are often referred to as a headphone. In the present specification, the terminology according to this is employed, and the term “headphone” used in this specification includes all of the so-called headphones and earphones as a target.

### [Prior Art Document]

### [Patent Document]

[Patent Document 1] Japanese Patent Laid-Open No. 2005-278177

[Patent Document 2] Japanese Patent Laid-Open No. 2005-354560

[Patent Document 3] Japanese Patent Laid-Open No. 2008-259157

### SUMMARY OF THE INVENTION

### Problem to be Solved by the Invention

The subject of the invention is to achieve and provide a headphone which can be connected to a plurality of external audio source devices used to arbitrarily select and combine sound information and musical compositions to be listened to simultaneously, information and compositions being obtained by converting an electrical signal input from the respective external audio source device into an audio signal and having different contents, and further, operated so turning up and down of the volume level and stopping-resuming of sound information and musical compositions having different contents of the respective audio source devices are performed independently and arbitrarily during listening.

### Means for Solving the Problem

In the invention according to claim 1, provided is a headphone to be used in a state of being brought into contact with and held against an auricle of an ear or an opening of the external auditory canal; the headphone includes a speaker unit which is provided in a housing in the main body for converting an electrical signal of an external audio device into an audio signal, and a connecting cord which has one end thereof connected with a connecting portion of the speaker unit and the other end thereof provided with a connector for electrically connecting with a desired external audio source device wherein a plurality or plural sets of speaker units to be respectively connected with a plurality of external audio source devices provided in the inside housing main body, and the respective connecting cords are provided for electrically connecting the plurality or plural sets of speaker units respectively with the external audio source devices to be connected.

In the invention according to claim 2, it is provided that in the headphone according to claim 1, means such as a volume controller and an on-off switch are provided for independently adjusting and operating the electrical signals of the plurality of the audio source devices at the appropriate middle position of the connecting cord.

### EFFECT OF THE INVENTION

As described above, according to the headphone of the invention, since a plurality of or plural sets of speaker units to be respectively connected to a plurality of audio source devices are provided in the main body of the headphone, and the external audio source devices to be connected and the speaker units are connected by respective connecting cords, the external audio source devices and the speaker units can be connected simultaneously so sound information and musical compositions having different contents can be arbitrarily selected and combined to be listened to simultaneously with one headphone. In addition thereto, by using an adjusting operation means provided in the middle of the connecting cord, Adjustment and operation of the headphone so as turning up and down of the volume level, stopping-resuming and the like of sound information and musical compositions having different contents of the respective audio source devices can be performed independently and arbitrarily during listening.

### BRIEF DESCRIPTION OF THE DRAWINGS

FIG. 1 is a cross-sectional view showing one example of a headphone according to the present invention.

FIG. 2 is a cross-sectional view showing another example of a headphone according to the present invention.

FIG. 3 is a front view showing an embodiment of a headphone according to the present invention.

FIG. 4 is a block chart showing an embodiment of a headphone according to the present invention.

FIG. 5 shows a cross-sectional view of a conventional headphone.

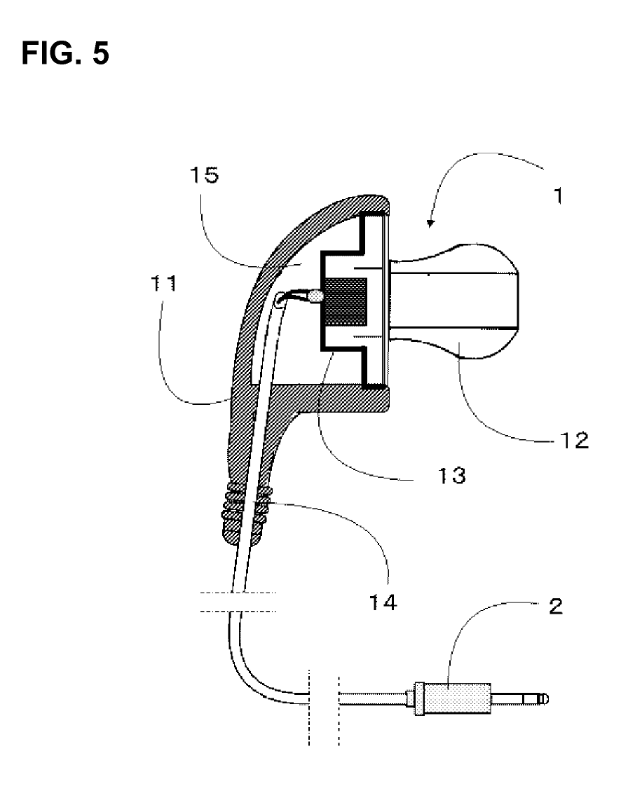

The invention has achieved an unprecedented headphone which can be connected simultaneously to a plurality of audio source devices respectively so sound information and musical compositions having different contents can be arbitrarily selected and combined to be listened to simultaneously using parts easily obtainable without incurring particular production man-hours and cost increase.

### Embodiment 1

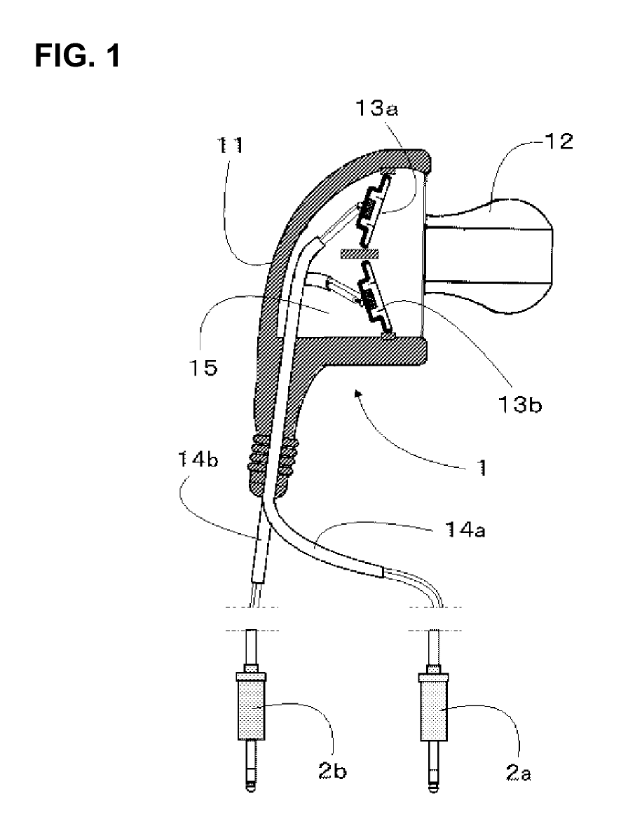

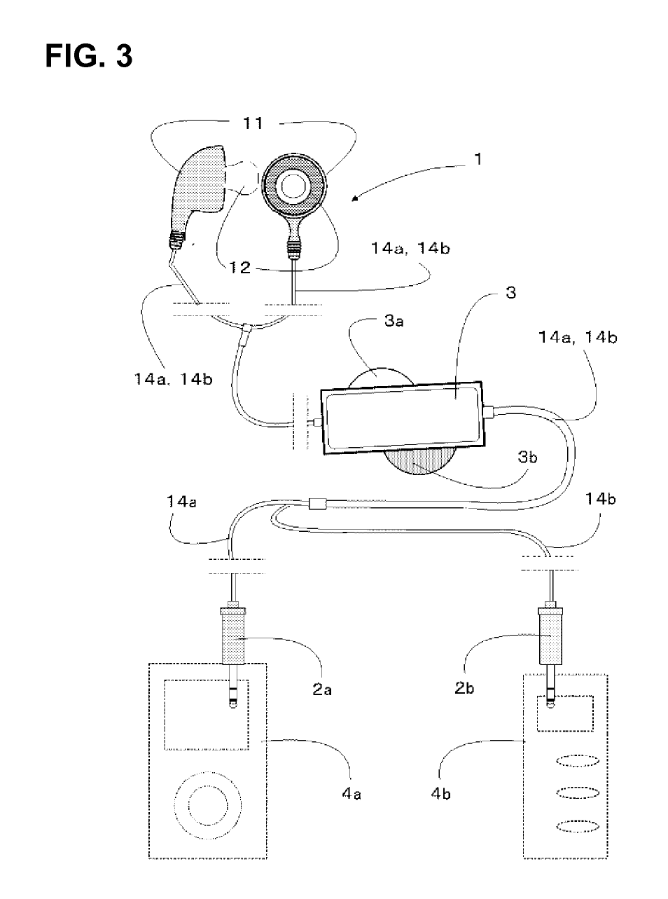

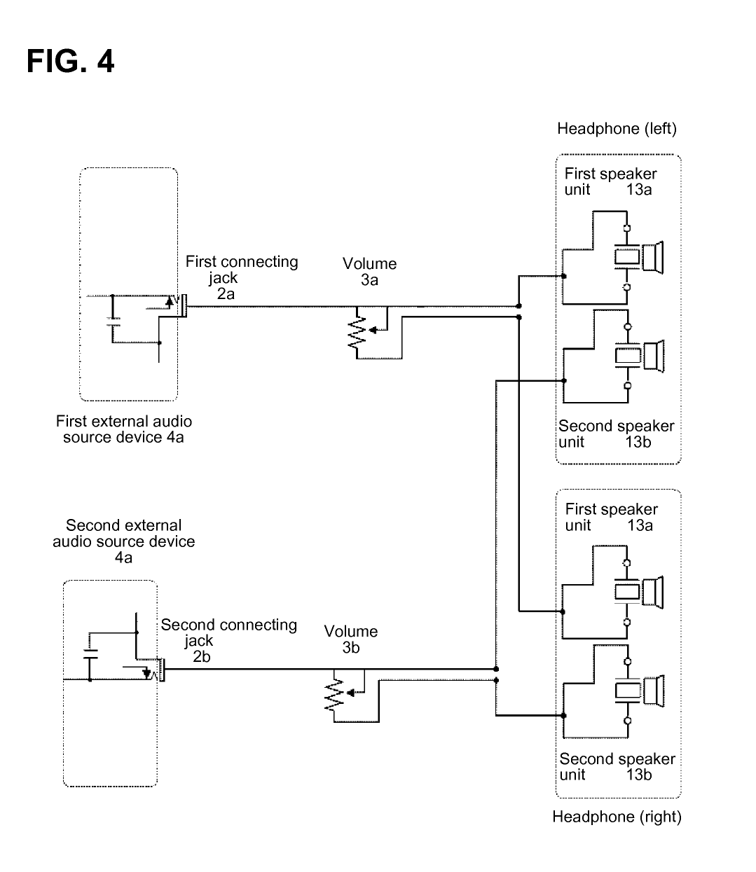

FIG. 1 shows an embodiment of a headphone according to the invention. FIG. 3 and FIG. 4 show one aspect of the embodiment. The embodiment shown in the figures is a so-called earphone type headphone in which an earplug 12 is inserted to an external auditory canal for listening, and which is a stereo type or hi-fi type headphone having a pair of main body parts for a right ear and a left ear.

A headphone 1 according to the embodiment has a hollow housing 15 formed inside a main body 11, the housing is provided with two speaker units of a first speaker unit 13a and second speaker unit 13b of a dynamic type which are connected to a plurality of different audio source devices to convert an input electrical signal into an audio signal that is able to be listened to and are fitted substantially in parallel with each other at an angle slightly inclined to an earplug. The speaker units 13a and 13b respectively have connecting terminals connected and fixed to one end of a first connecting cord 14a and a second connecting cord 14b for connecting with the different external audio source devices to be corresponded respectively to by the speaker units 13a and 13b. The connecting cords 14a and 14b arranged so as to extend outside the main body 11 of the headphone 1 have the other ends which are not fixed provided with a first connecting jack 2a and a second connecting jack 2b which are to be inserted for connecting to connecting portions of the respective external audio source devices (see FIG. 1).

As shown in FIG. 3 and FIG. 4, the first connecting cord 14a and the second connecting cord 14b for connecting the first speaker unit 13a and the second speaker unit 13b fitted in the main body 11 of each of a pair of right and left headphones 1 with the plurality of different audio source devices respectively (a first external audio source device 4a and a second external audio source device 4b) are branched into one on the side of the flexible ends provided with the first connecting jack 2a and the second connecting jack 2b as the connector for connecting with the external audio source devices, and covered so as to be in a parallel state at an appropriated position in the direction of a middle portion thereof. In order to be connected and fixed to terminal portions of two pairs of the first speaker unit 13a and second speaker unit 13b fitted in the pair of right and left main bodies 11, the first connecting cord 14a and the second connecting cord 14b are respectively branched into two at an appropriated position in the direction of the main body 11 of the headphone 1, one pair of the first connecting cord 14a and second connecting cord 14b respectively are connected with the terminal portions of the first speaker unit 13a and the second speaker unit fitted in the main body 11 for the left ear, and the other pair of the first connecting cord 14a and second connecting cord 14b respectively are connected with the terminal portions of the first speaker unit 13a and the second speaker unit in the main body 11 for the right ear.

Further, in the embodiment shown in FIG. 3 and FIG. 4, a volume controller 3 is provided in the middle position of the first connecting cord 14a and the second connecting cord 14b for connecting the external audio source devices 4a and 4b with two pairs of speaker unit 13a and 13b. A first volume 3a and a second volume 3b each having an adjustment dial are connected to the connecting cord 14a and 14b respectively. (Note that in the embodiment, the first connecting cord 14a and the second connecting cord 14b which are branched into one on the side of the flexible ends are respectively branched into two at the position where the volume controller 3 is provided.)

The headphone of the embodiment has the configuration described above and is used according to the embodiment as shown. Therefore, the different electrical signals output from the two different external audio source devices 4a and 4b are respectively converted into audio signals in the speaker units 13a and 13b connected so as to be correspondent to the devices 4a and 4b respectively. Thus, if only one headphone 1 provided with the pair of right and left main bodies 11 having the speaker units 13a and 13b fitted therein is worn, it is possible to listen to and enjoy sound information and musical compositions of two kinds of different contents which are arbitrarily selected and combined.

Moreover, in the headphone of the embodiment, in the middle position of the two kinds of connecting cords 14a and 14b for connecting the external audio source devices 4a and 4b with the speaker units 13a and 13b, the volumes 3a and 3b are provided which adjust and operate respectively and independently the electrical signals output via the connecting cords to arbitrarily turn up and down the volume of the audio signals obtained on the side of the speaker units 13a and 13b. Therefore, for example, in a case of simultaneously listening to sound information of the lecture recorded in the voice recorder with the musical composition being played by the digital audio player in the background, when the user wants to concentrate on the important part of the sound information of the lecture, it is possible to turn down the volume of only the musical composition to the lowest extent or turn up the volume of only the lecture and the like, that is, arbitrarily adjustment and usage according to the situation and time is allowed, truly meeting the demand for simultaneous listening.

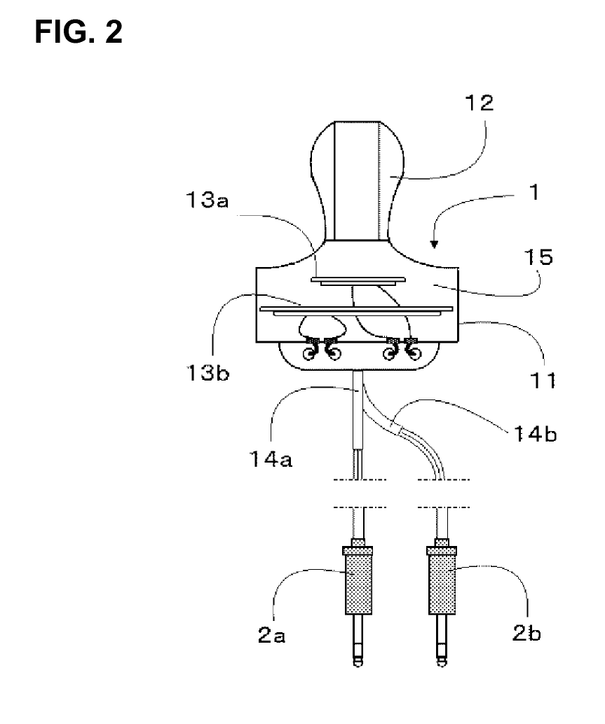

Note that in the embodiment, as the speaker units 13a and 13b are fitted in the housing 15 formed inside the main body 11 of the headphone 1, a dynamic speaker unit is used in which a permanent magnet is arranged in a hollow portion of a voice coil attached with a diaphragm so an electrical signal is applied to the voice coil in a magnetic field of the permanent magnet to cause vibrations. However, it is only for the sake of explanation, and needless to say, all types of speaker units can be used to attain the embodiment. FIG. 2 shows an example using another type of speaker unit which uses speaker units 13a and 13b of a crystal type in which a piezoceramic attached with a metal plate is used as a vibration thin film. Since in the crystal speaker unit the one thinner and smaller than the dynamic speaker unit can be used, the speaker units are fitted in a coaxial fashion so the small sized first speaker unit 13a suitable for playing sound information is arranged at a position in the centre and in front of the relatively large sized second speaker unit 13b suitable for playing musical compositions.

Additionally, in the embodiment, the volume controller 3 is provided in the middle portion of the connecting cords 14a and 14b for connecting the external audio source devices 4a and 4b with the speaker units 13a and 13b respectively. However, it is also possible to arbitrarily provide other adjusting operation means such as an on-off switch to be operated independently for each of the connecting cords 14a and 14b, which are included in a relevant range disclosed in the invention.

Further, the embodiment's two kinds of speaker units 13a and 13b are used for listening to different sound information and musical compositions so as to correspond to two external audio source devices; however, this number does not mean much. It is technically possible to provide three or more speaker units to correspond to three or more external audio source devices, which is not particularly affected by whether or not there is a realistic request or advantage thereof.

### REFERENCE NUMERALS

1 Headphone
2 Connecting jack
2a 1^{st} Connecting jack
2b 2^{nd} Connecting jack
3 Volume controller
3a 1^{st} Volume
3b 2^{nd} Volume
4a 1^{st} External sound equipment
4b 2^{nd} External sound equipment
11 Body
12 Earplug
13 Speaker unit
13a 1^{st} Speaker unit
13b 2^{nd} Speaker unit
14 Connecting cord
14a 1^{st} Connecting cord
14b 2^{nd} Connecting cord
15 Housing

1. A headphone used in a state of being brought into contact with and held against an auricle of an ear or an opening of the external auditory canal, comprising
a speaker unit which is provided in a housing in the main body for converting an electrical signal of an external audio device into an audio signal, and
a connecting cord which has one end thereof connected with a connecting portion of the speaker unit and the other end thereof provided with a connector for electrically connecting with a desired external audio source device,
wherein a plurality or plural sets of speaker units to be respectively connected with a plurality of external audio source devices are provided in the inside housing main body, and the respective connecting cords are provided for electrically connecting the plurality or plural sets of speaker units respectively with the external audio source devices to be connected.

2. The headphone according to claim 1, means such as a volume controller and an on-off switch are provided for independently adjusting and operating the electrical signals of the plurality of the audio source devices at the appropriate middle position of the connecting cord.
